(19) United States
(12) Patent Application Publication
(10) Pub. No.: US 2026/0362878 A1
(43) Pub. Date: Nov. 12, 2026

(54) SEMICONDUCTOR LIGHT-EMITTING ELEMENT AND DISPLAY DEVICE

(71) Applicant: LG ELECTRONICS INC., Seoul (KR)

(72) Inventors: Sunghyun HWANG, Seoul (KR); Byungjun KANG, Seoul (KR); Kiseong JEON, Seoul (KR)

(73) Assignee: LG ELECTRONICS INC., Seoul (KR)

(21) Appl. No.: 19/100,280

(22) PCT Filed: Aug. 8, 2022
(86) PCT No.: PCT/KR2022/011798

§ 371 Date: Jan. 31, 2025

(51) Int. Cl. H10H 29/49; H10H 20/831; H10H 20/84

(52) U.S. Cl. CPC H10H 29/49; H10H 20/8314; H10H 20/84

(57) ABSTRACT

The semiconductor light-emitting element may include a light-emitting layer, a passivation layer configured to surround the light-emitting layer, a lower electrode on a lower side of the light-emitting layer, and a side electrode configured to extend from an end of the lower electrode onto a side portion of the light-emitting layer. The side electrode is spaced apart from the side portion of the light-emitting layer.

### TECHNICAL FIELD

The embodiment relates to a semiconductor light-emitting element and a display device.

### BACKGROUND ART

A large-area display includes a liquid crystal display (LCD), an OLED display, and a micro-LED display.

The micro-LED display is a display that uses a micro-LED, which is a semiconductor light-emitting element with a diameter or cross-sectional area of 100 μm or less, as a display element.

Since the micro-LED display uses a micro-LED, which is a semiconductor light-emitting element, as a display element, it has excellent performance in many characteristics such as contrast ratio, response speed, color reproducibility, viewing angle, brightness, resolution, lifespan, luminescence efficiency, or luminance.

In particular, the micro-LED display has the advantage of being able to freely adjust the size or resolution by separating and combining the screens in a modular manner, and the advantage of being able to implement a flexible display.

However, since a large micro-LED display requires millions or more micro-LEDs, there is a technical problem that makes it difficult to quickly and accurately transfer micro-LEDs to a display panel.

Recently developed transfer technologies include a pick and place process, a laser lift-off method, and a self-assembly method.

Among these, the self-assembly method is a method in which semiconductor light-emitting elements find their assembly positions within a fluid, which is advantageous for implementing a large-screen display device.

However, research on the technology for manufacturing a display through self-assembly of micro-LEDs is still insufficient.

In particular, in the case of rapidly transferring millions or more semiconductor light-emitting elements to a large display in the conventional technology, the transfer speed can be improved, but the transfer error rate can increase, which causes a technical problem in that the transfer yield decreases.

In the related technology, a self-assembly transfer process using dielectrophoresis (DEP) has been attempted, but there is a problem that the self-assembly rate is low due to the non-uniformity of the DEP force.

Meanwhile, an electrical connection on a lower side of a semiconductor light-emitting element was attempted using a bonding method that heats/pressures the semiconductor light-emitting element. However, there are problems such as poor lighting due to poor bonding or the need for additional wiring.

To solve these problems, an electrical connection using a side electrode was attempted.

FIG. 1 is a cross-sectional view illustrating a semiconductor light-emitting element according to a non-public internal technology.

As illustrated in FIG. 1, the semiconductor light-emitting element 1 includes a passivation layer 3 surrounding a light-emitting layer 2 and a side electrode 4 on a side portion of the light-emitting layer 2.

The side electrode 4 is formed on the side portion as well as the lower side of the light-emitting layer 2 by a sputtering process. The side electrode 4 is formed up to the side portion that contacts an upper side of the light-emitting layer 2.

FIG. 2 is a cross-sectional view illustrating a display device equipped with a semiconductor light-emitting element according to a non-public internal technology.

As illustrated in FIG. 2, a semiconductor light-emitting element 1 is disposed in an assembly hole 5H of a partition wall 5, and an insulating layer 6 is disposed around the semiconductor light-emitting element 1.

Specifically, an insulating layer 6 is formed on the partition wall 5, and a planarization process is performed so that the insulating layer 6 is removed until the passivation layer 3 on the upper side of the partition wall 5 and the semiconductor light-emitting element 1 is exposed. Accordingly, the insulating layer 6 is formed around the semiconductor light-emitting element 1 in the assembly hole 5H. Thereafter, the passivation layer 3 on the upper side of the semiconductor light-emitting element 1 is removed so that the upper surface of the semiconductor light-emitting element is exposed.

Thereafter, a first electrode wiring 7 and a second electrode wiring 8 are formed. The first electrode wiring 7 is connected to the side electrode 4 through the insulating layer 6, and the second electrode wiring 8 is connected to an upper side of the light-emitting layer 2.

However, as illustrated in FIG. 2, the side electrode 4 and the second electrode wiring 8 formed on the side portion of the semiconductor light-emitting element 1 are electrically short-circuited, resulting in a lighting failure. That is, the side electrode 4 is formed at the same height as an entire region of a side portion of the semiconductor light-emitting element 1, particularly the upper side of the light-emitting layer 2, and is exposed together with the upper side of the light-emitting layer 2 during the planarization process of the insulating layer 6. Therefore, when the second electrode wiring 8 is formed on the insulating layer 6 and the light-emitting layer 2, the exposed side electrode 4 comes into contact with the second electrode wiring 8, resulting in an electrical short-circuit failure between the side electrode 4 and the second electrode wiring 8. Accordingly, a lighting failure occurs in which the semiconductor light-emitting element 1 does not emit light.

In order to solve this problem, the side electrode 4 must be formed in the lower region of the side portion of the light-emitting layer 2. However, since the side electrode 4 is formed by randomly attaching metal particles onto the light-emitting layer 2 by the sputtering process, it is impossible to control the side electrode 4 to be formed only in the lower region of the side portion of the light-emitting layer 2.

Therefore, the development of a semiconductor light-emitting element having a new structure including the side electrode 4 is urgently required.

### DISCLOSURE

### Technical Problem

An object of the embodiment is to solve the foregoing and other problems.

Another object of the embodiment is to provide a semiconductor light-emitting element comprising a side electrode having a new structure.

In addition, another object of the embodiment is to provide a display device capable of preventing an electrical short between the side electrode and the second electrode wiring.

In addition, another object of the embodiment is to provide a display device capable of preventing a lighting failure.

In addition, another object of the embodiment is to provide a display device capable of improving fixing force.

In addition, another object of the embodiment is to provide a display device capable of improving assembly speed.

The technical problems of the embodiments are not limited to those described in this item and comprise those that may be understood through the description of the invention.

### Technical Solution

According to one aspect of the embodiment to achieve the above or other objects,

A semiconductor light-emitting element may comprise: a light-emitting layer; a passivation layer configured to surround the light-emitting layer; a lower electrode on a lower side of the light-emitting layer; and a side electrode configured to extend from an end of the lower electrode onto a side portion of the light-emitting layer,

The side electrode is spaced apart from the side portion of the light-emitting layer.

The side electrode may be disposed along a perimeter of the side portion of the light-emitting layer.

The semiconductor light-emitting element may comprise:

a recess between the side electrode and the side portion of the light-emitting layer.

The side electrode may be disposed in a diagonal direction with respect to the lower electrode.

The light-emitting layer may comprise: a first conductivity type semiconductor layer; an active layer on the first conductivity type semiconductor layer; and a second conductivity type semiconductor layer on the active layer.

A length of the side electrode may be smaller than a thickness of the first conductivity type semiconductor layer of the light-emitting layer.

The side portion of the light-emitting layer may have an acute angle with respect to the lower side of the light-emitting layer.

The side electrode may have an obtuse angle with respect to a horizontal surface of the lower electrode.

A separation distance between the side electrode and the side portion of the light-emitting layer may increase along an upward direction.

The side electrode may have an acute angle with respect to the side portion of the light-emitting layer.

The side electrode may have an obtuse angle with respect to the side portion of the light-emitting layer.

The passivation layer may have an inner side surface in contact with the side portion of the light-emitting layer and an outer side surface in contact with the side electrode, and a width between the inner side surface and the outer side surface may decrease along a downward direction.

The outer side surface may have an acute or obtuse angle with respect to the inner side surface.

The lower electrode and the side electrode may comprise a magnetic layer.

According to another aspect of the embodiment,

A display device may comprise: a substrate; a first assembling wiring on the substrate; a second assembling wiring on the substrate; a partition wall having an assembly hole on the first assembling wiring and the second assembling wiring; a semiconductor light-emitting element in the assembly hole; a first electrode wiring on a side portion of the semiconductor light-emitting element; and a second electrode wiring on an upper side of the semiconductor light-emitting element.

The semiconductor light-emitting element may comprise: a light-emitting layer; a passivation layer configured to surround the light-emitting layer; a lower electrode on a lower side of the light-emitting layer; and a side electrode configured to extend from an end of the lower electrode onto a side portion of the light-emitting layer, and the side electrode may be spaced apart from the side portion of the light-emitting layer, and

The first electrode wiring may be disposed between the side portion of the light-emitting layer and the side electrode.

The first electrode wiring may be disposed on an outer side surface of the side electrode.

The first electrode wiring may be connected to the side electrode along a perimeter of the semiconductor light-emitting element.

The display device may comprise: an insulating layer in the assembly hole, the first electrode wiring and the second electrode wiring may be disposed on a same horizontal line, and the first electrode wiring may be connected to the side electrode of the semiconductor light-emitting element by penetrating the insulating layer.

The first electrode wiring may be connected to at least one of the first assembling wiring or the second assembling wiring.

### Advantageous Effects

As illustrated in FIGS. 9 and 10, a side electrode 154-2 of a semiconductor light-emitting element 150 may be positioned to be spaced apart from a side portion of a light-emitting layer 150a. That is, the side electrode 154-2 of the semiconductor light-emitting element 150 may not be in contact with the side portion of the light-emitting layer 150a. Accordingly, the side electrode 154-2 of the semiconductor light-emitting element 150 may be not formed on the upper side of the light-emitting layer 150a, so that even if the second electrode wiring 372 electrically connected to an upper side of the first semiconductor light-emitting element 150-1 is formed as illustrated in FIG. 24, the second electrode wiring 372 may be not electrically short-circuited between the side electrode 154-2 of the first semiconductor light-emitting element 150-1. Accordingly, since a lighting failure due to an electrical short is prevented, the lighting yield can be improved.

Meanwhile, as illustrated in FIG. 24 and FIG. 26, since a first electrode wiring 371 is disposed not only between a side portion of the light-emitting layer 150a of a first semiconductor light-emitting element 150-1 and a side electrode 154-2, but also on an outer side surface of the side electrode 154-2, the fixing force of the first semiconductor light-emitting element 150-1 can be strengthened. Likewise, as illustrated in FIG. 23, since the first electrode wiring 371 is disposed around the corresponding side electrode 154-2 in each of the second semiconductor light-emitting element 150-2 and the third semiconductor light-emitting element 150-3, the fixing force of each of the second semiconductor light-emitting element 150-2 and the third semiconductor light-emitting element 150-3 can be strengthened.

Meanwhile, as illustrated in FIGS. 9 and 10, since the first electrode 154 comprising a lower electrode 154-1 and a side electrode 154-2 comprises a magnetic layer (154c in FIG. 15), a size of the magnetic layer 154c may be enlarged, so that the semiconductor light-emitting element 150 can respond more quickly to the movement of the magnet, thereby improving the assembly speed of the semiconductor light-emitting element 150.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### DESCRIPTION OF DRAWINGS

FIG. 1 is a cross-sectional view illustrating a semiconductor light-emitting element according to a non-public internal technology.

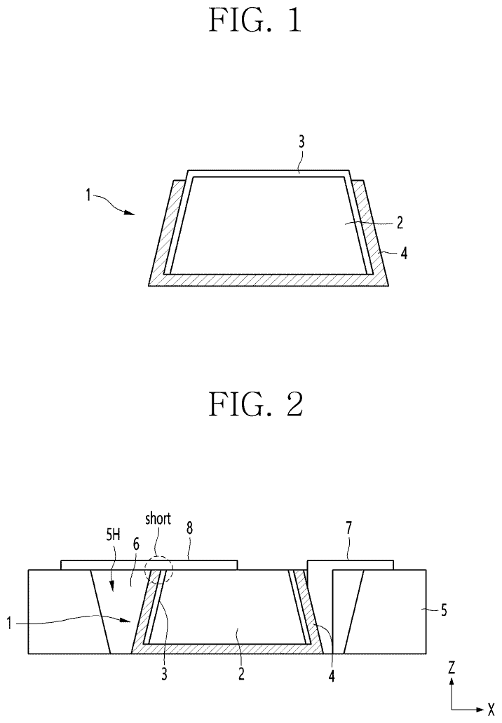

FIG. 2 is a cross-sectional view illustrating a display device equipped with a semiconductor light-emitting element according to a non-public internal technology.

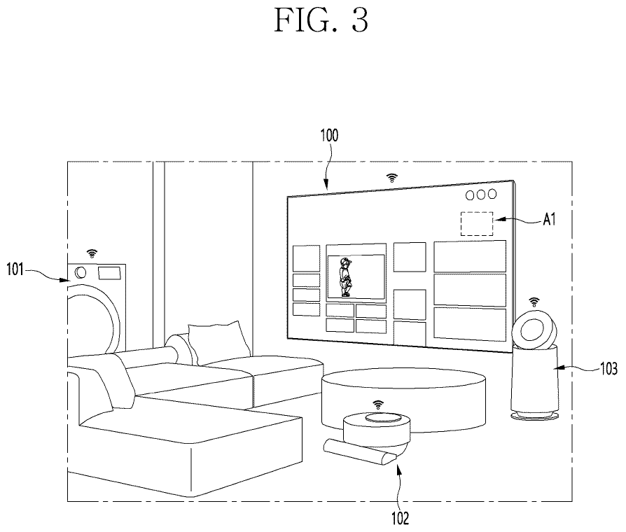

FIG. 3 illustrates a living room of a house in which a display device according to an embodiment is disposed.

FIG. 4 is a block diagram schematically showing a display device according to an embodiment.

FIG. 5 is a circuit diagram showing an example of a pixel of FIG. 4.

FIG. 6 is an enlarged view of a first panel region in the display device of FIG. 3.

FIG. 7 is an enlarged view of a region A2 of FIG. 6.

FIG. 8 is a drawing illustrating an example in which a light-emitting element according to an embodiment is assembled on a substrate by a self-assembly method.

FIG. 9 is a perspective view illustrating a semiconductor light-emitting element according to an embodiment.

FIG. 10 is a cross-sectional view illustrating a semiconductor light-emitting element according to an embodiment.

FIG. 11 illustrates the shape of a first electrode in a semiconductor light-emitting element according to an embodiment.

FIG. 12 is an exemplary view illustrating the arrangement relationship between a first electrode and a semiconductor light-emitting element according to an embodiment.

FIG. 13 is another exemplary view illustrating the arrangement relationship between a first electrode and a semiconductor light-emitting element according to an embodiment.

FIG. 14 is an enlarged view illustrating a region X in FIG. 10.

FIG. 15 illustrates a multilayer structure of a first electrode in a semiconductor light-emitting element according to an embodiment.

FIGS. 16 to 22 illustrate a manufacturing process of a semiconductor light-emitting element according to an embodiment.

FIG. 23 is a circuit diagram illustrating a display device according to the first embodiment.

FIG. 24 is a cross-sectional view illustrating a display device according to the first embodiment.

FIG. 25 is a plan view illustrating the first assembling wiring and the second assembling wiring disposed in the assembly hole.

FIG. 26 is a cross-sectional view illustrating a display device according to the second embodiment.

The sizes, shapes, dimensions, etc. of elements illustrated in the drawings may differ from actual ones. In addition, even if the same elements are illustrated in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there may be directly on the other element or be other intermediate elements therebetween.

The display device described in this specification may comprise a TV, a signage, a mobile phone, a smart phone, a head-up display (HUD) for an automobile, a backlight unit for a laptop computer, a display for VR, AR, or MR (mixed reality), etc. However, the configuration according to the embodiment described in this specification may be applied to a device capable of displaying, even if it is a new product type developed in the future.

The following describes a light-emitting element according to an embodiment and a display device comprising the same.

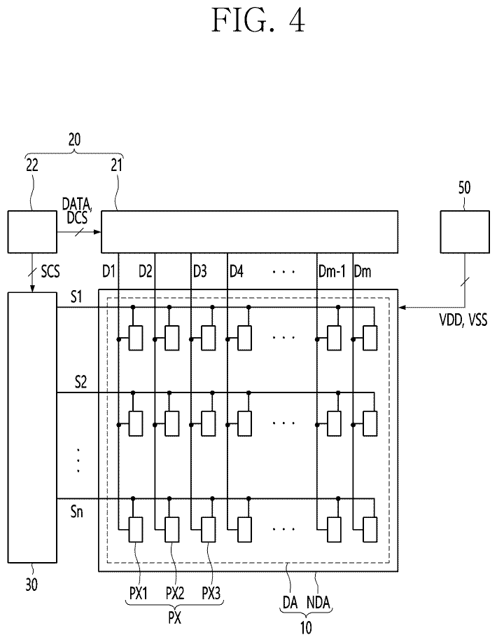

FIG. 3 illustrates a living room of a house in which a display device according to an embodiment is disposed.

Referring to FIG. 3, the display device 100 according to the embodiment may display the status of various electronic products such as a washing machine 101, a robot vacuum cleaner 102, and an air purifier 103, and may communicate with each electronic product based on IOT and control each electronic product based on user setting data.

The display device 100 according to the embodiment may comprise a flexible display manufactured on a thin and flexible substrate. The flexible display may be bent or rolled like paper while maintaining the characteristics of an existing flat panel display.

In the flexible display, visual information may be implemented by independently controlling the light emission of unit pixels disposed in a matrix form. A unit pixel means a minimum unit for implementing one color. The unit pixel of the flexible display may be implemented by a light-emitting element. In the embodiment, the light-emitting element may be a micro-LED or a nano-LED, but is not limited thereto.

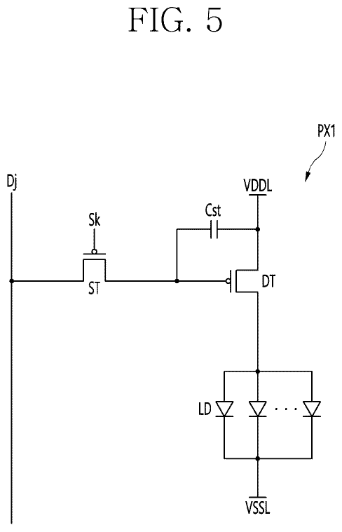

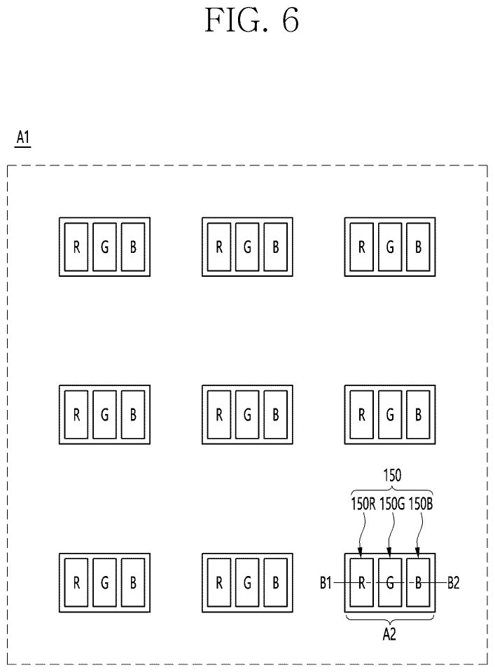

FIG. 4 is a block diagram schematically showing a display device according to an embodiment, and FIG. 5 is a circuit diagram showing an example of a pixel of FIG. 4.

Referring to FIGS. 4 and 5, the display device according to the embodiment may comprise a display panel 10, a driving circuit 20, a scan driving unit 30, and a power supply circuit 50.

The display device 100 of the embodiment may drive the light-emitting element in an active matrix (AM) manner or a passive matrix (PM) manner.

The driving circuit 20 may comprise a data driving unit 21 and a timing control unit 22.

The display panel 10 may be formed in a rectangular shape, but is not limited thereto. That is, the display panel 10 may be formed in a circular or oval shape. At least one side of the display panel 10 may be formed to be bent at a predetermined curvature.

The display panel 10 may be divided into a display region DA and a non-display region NDA disposed around the display region DA. The display region DA is a region where subpixels PX1, PX2, and PX3 are formed to display an image. The display panel 10 may comprise data lines (D1 to Dm, m is an integer greater than or equal to 2), scan lines (S1 to Sn, n is an integer greater than or equal to 2) intersecting the data lines D1 to Dm, a high-potential voltage line VDDL to which a high-potential voltage is supplied, a low-potential voltage line VSSL to which a low-potential voltage VSS is supplied, and subpixels PX1, PX2, and PX3 connected to the data lines D1 to Dm and the scan lines S1 to Sn.

The subpixels PX1, PX2, and PX3 may comprise a first subpixel PX1, a second subpixel PX2, and a third subpixel PX3, respectively. The first subpixel PX1 may emit a first color light of a first main wavelength, the second subpixel PX2 may emit a second color light of a second main wavelength, and the third subpixel PX3 may emit a third color light of a third main wavelength. The first color light may be red light, the second color light may be green light, and the third color light may be blue light, but is not limited thereto. In addition, although FIG. 4 exemplifies that each of the subpixels PX1, PX2, and PX3 comprises three subpixels, it is not limited thereto. That is, the subpixels PX1, PX2, and PX3 may comprise four or more subpixels.

The first subpixel PX1, the second subpixel PX2, and the third subpixel PX3 may each be connected to at least one of the data lines D1 to Dm, at least one of the scan lines S1 to Sn, and the high-potential voltage line VDDL. The first subpixel PX1 may comprise light-emitting elements LD, a plurality of transistors for supplying current to the light-emitting elements LD, and at least one capacitor Cst, as illustrated in FIG. 5.

Although not illustrated in the drawing, each of the first subpixel PX1, the second subpixel PX2, and the third subpixel PX3 may comprise only one light-emitting element LD and at least one capacitor Cst.

Each of the light-emitting elements LD may be a semiconductor light-emitting diode comprising a first electrode, a plurality of conductivity type semiconductor layers, and a second electrode. Here, the first electrode may be an anode electrode, and the second electrode may be a cathode electrode, but is not limited thereto.

The light-emitting element LD may be one of a lateral-type light-emitting element, a flip-chip type light-emitting element, and a vertical-type light-emitting element.

The plurality of transistors may comprise a driving transistor DT for supplying current to the light-emitting elements LD, and a scan transistor ST for supplying a data voltage to a gate electrode of the driving transistor DT, as illustrated in FIG. 5. The driving transistor DT may comprise a gate electrode connected to a source electrode of the scan transistor ST, a source electrode connected to a high-potential voltage line VDDL to which a high-potential voltage is applied, and a drain electrode connected to the first electrodes of the light-emitting elements LD. The scan transistor ST may comprise a gate electrode connected to a scan line (Sk, where k is an integer satisfying 1≤k≤n), a source electrode connected to the gate electrode of the driving transistor DT, and a drain electrode connected to a data line (Dj, where j is an integer satisfying 1≤j≤m).

A capacitor Cst is formed between the gate electrode and the source electrode of the driving transistor DT. The storage capacitor Cst charges a difference value between the gate voltage and the source voltage of the driving transistor DT.

The driving transistor DT and the scan transistor ST may be formed as thin film transistors. In addition, in FIG. 5, the driving transistor DT and the scan transistor ST are described as being formed as P-type metal oxide semiconductor field effect transistors (MOSFET), but the present invention is not limited thereto. The driving transistor DT and the scan transistor ST may also be formed as N-type MOSFET. In this instance, the positions of the source electrode and the drain electrode of each of the driving transistor DT and the scan transistor ST may be changed.

In addition, in FIG. 5, the first subpixel PX1, the second subpixel PX2, and the third subpixel PX3 are exemplified as comprising 2T1C (2 Transistor-1 capacitor) having one driving transistor DT, one scan transistor ST, and one capacitor Cst, but the present invention is not limited thereto. The first subpixel PX1, the second subpixel PX2, and the third subpixel PX3 may each comprise a plurality of scan transistors ST and a plurality of capacitors Cst.

The second subpixel PX2 and the third subpixel PX3 may be configured as substantially the same circuit diagram as the first subpixel PX1, so that a detailed description thereof is omitted.

The driving circuit 20 outputs signals and voltages for driving the display panel 10. To this end, the driving circuit 20 may comprise a data driving unit 21 and a timing control unit 22.

The data driving unit 21 receives digital video data DATA and a source control signal DCS from the timing control unit 22. The data driving unit 21 converts the digital video data DATA into analog data voltages according to the source control signal DCS and supplies the converted data to the data lines D1 to Dm of the display panel 10.

The timing control unit 22 receives digital video data DATA and timing signals from the host system. The timing signals may comprise a vertical synchronization signal, a horizontal synchronization signal, a data enable signal, and a dot clock. The host system may be an application processor of a smartphone or tablet PC, a monitor, a system on chip of a TV, etc.

The timing control unit 22 generates control signals for controlling the operation timing of the data driving unit 21 and the scan driving unit 30. The control signals may comprise a source control signal DCS for controlling the operation timing of the data driving unit 21 and a scan control signal SCS for controlling the operation timing of the scan driving unit 30.

The driving circuit 20 may be disposed in a non-display region NDA provided on one side of the display panel 10. The driving circuit 20 may be formed as an integrated circuit (IC) and mounted on the display panel 10 using a chip on glass (COG) method, a chip on plastic (COP) method, or an ultrasonic bonding method, but the present invention is not limited thereto. For example, the driving circuit 20 may be mounted on a circuit board (not illustrated) other than the display panel 10.

The data driving unit 21 may be mounted on the display panel 10 using a chip on glass (COG) method, a chip on plastic (COP) method, or an ultrasonic bonding method, and the timing control unit 22 may be mounted on the circuit board.

The scan driving unit 30 receives a scan control signal SCS from the timing control unit 22. The scan driving unit 30 generates scan signals according to the scan control signal SCS and supplies them to the scan lines S1 to Sn of the display panel 10. The scan driving unit 30 may be formed in a non-display region NDA of the display panel 10 comprising a plurality of transistors. Alternatively, the scan driving unit 30 may be formed as an integrated circuit, in which case it may be mounted on a gate flexible film attached to the other side of the display panel 10.

The circuit board may be attached to pads provided on one edge of the display panel 10 using an anisotropic conductive film. As a result, lead lines of the circuit board may be electrically connected to the pads. The circuit board may be a flexible film such as a flexible printed circuit board, a printed circuit board, or a chip on film. The circuit board may be bent to a lower part of the display panel 10. As a result, one side of the circuit board may be attached to one edge of the display panel 10, and the other side may be disposed on the lower part of the display panel 10 and connected to a system board on which a host system is mounted.

The power supply circuit 50 may generate voltages required for driving the display panel 10 from a main power applied from the system board and supply the voltages to the display panel 10. For example, the power supply circuit 50 may generate a high-potential voltage VDD and a low-potential voltage VSS for driving the light-emitting elements LD of the display panel 10 from the main power supply and supply them to the high-potential voltage line VDDL and the low-potential voltage line VSSL of the display panel 10. In addition, the power supply circuit 50 may generate and supply driving voltages for driving the driving circuit 20 and the scan driving unit 30 from the main power supply.

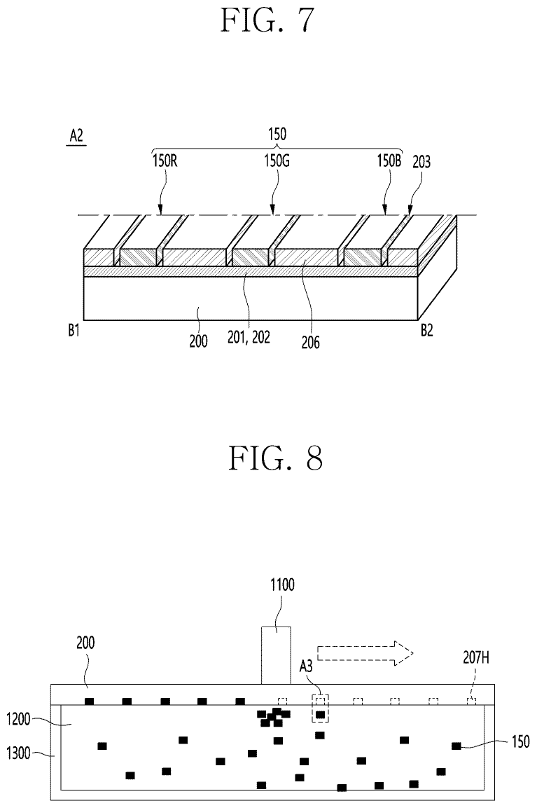

FIG. 6 is an enlarged view of the first panel region in the display device of FIG. 3.

Referring to FIG. 6, the display device 100 of the embodiment may be manufactured by mechanically and electrically connecting a plurality of panel regions such as the first panel region Al by tiling.

The first panel region Al may comprise a plurality of semiconductor light-emitting elements 150 disposed for each unit pixel (PX of FIG. 4).

For example, the unit subpixels PX1, PX2, and PX3 may comprise a first subpixel PX1, a second subpixel PX2, and a third subpixel PX3. For example, a plurality of red semiconductor light-emitting elements 150R may be disposed in the first subpixel PX1, a plurality of green semiconductor light-emitting elements 150G may be disposed in the second subpixel PX2, and a plurality of blue semiconductor light-emitting elements 150B may be disposed in the third subpixel PX3. The unit subpixels PX1, PX2, and PX3 may further comprise a fourth subpixel in which no semiconductor light-emitting elements are disposed, but is not limited thereto.

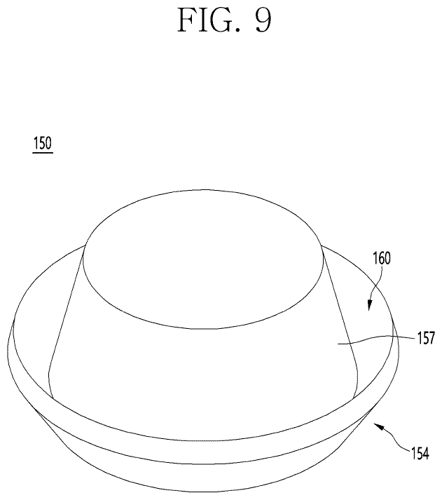

FIG. 7 is an enlarged view of the A2 region of FIG. 6.

Referring to FIG. 7, the display device 100 of the embodiment may comprise a substrate 200, assembling wirings 201 and 202, an insulating layer 206, and a plurality of semiconductor light-emitting elements 150. More components may be included than these.

The assembling wirings may comprise a first assembling wiring 201 and a second assembling wiring 202 that are spaced apart from each other. The first assembling wiring 201 and the second assembling wiring 202 may be provided to generate a dielectrophoretic force (DEP) to assemble the semiconductor light-emitting element 150. For example, the semiconductor light-emitting element 150 may be one of a lateral-type semiconductor light-emitting element, a flip-chip type semiconductor light-emitting element, and a vertical-type semiconductor light-emitting element.

The semiconductor light-emitting element 150 may comprise, but is not limited to, a red semiconductor light-emitting element 150R, a green semiconductor light-emitting element 150G, and a blue semiconductor light-emitting element 150B to form a unit pixel (subpixel), and may also comprise a red phosphor and a green phosphor to implement red and green, respectively.

The substrate 200 may be a supporting member that supports components disposed on the substrate 200 or a protective member that protects the components.

The substrate 200 may be a rigid substrate or a flexible substrate. The substrate 200 may be formed of sapphire, glass, silicon, or polyimide. In addition, the substrate 200 may comprise a flexible material such as polyethylene naphthalate (PEN), polyethylene terephthalate (PET). In addition, the substrate 200 may be a transparent material, but is not limited thereto. The substrate 200 may function as a support substrate in a display panel, and may also function as an assembly substrate when self-assembling a light-emitting element.

The substrate 200 may be a backplane equipped with circuits in the subpixels PX1, PX2 and PX3 as illustrated in FIGS. 4 and 5, such as transistors ST and DT, capacitors Cst, signal wirings, etc., but is not limited thereto.

The insulating layer 206 may comprise an insulating and flexible organic material such as polyimide, PAC, PEN, PET, polymer, etc., or an inorganic material such as silicon oxide (SiO2) or silicon nitride series (SiNx), and may be formed integrally with the substrate 200 to form a single substrate.

The insulating layer 206 may be a conductive adhesive layer having adhesiveness and conductivity, and the conductive adhesive layer may have flexibility to enable a flexible function of the display device. For example, the insulating layer 206 may be a conductive adhesive layer such as an anisotropic conductive film (ACF) or an anisotropic conductive medium, a solution containing conductive particles, etc. The conductive adhesive layer may be a layer that is electrically conductive in a direction vertical to the thickness, or electrically insulating in a direction horizontal to the thickness.

The insulating layer 206 may comprise an assembly hole 203 for inserting a semiconductor light-emitting element 150. Therefore, when self-assembling, the semiconductor light-emitting element 150 may be easily inserted into the assembly hole 203 of the insulating layer 206. The assembly hole 203 may be called an insertion hole, a fixing hole, an alignment hole, etc. The assembly hole 203 may also be called a hole.

The assembly hole 203 may be called a hole, a groove, a recess, a pocket, etc.

The assembly hole 203 may be different depending on the shape of the semiconductor light-emitting element 150. For example, the red semiconductor light-emitting element, the green semiconductor light-emitting element, and the blue semiconductor light-emitting element each have different shapes, and the assembly hole 203 having a shape corresponding to the shape of each of these semiconductor light-emitting elements may be provided. For example, the assembly hole 203 may comprise a first assembly hole for assembling the red semiconductor light-emitting element, a second assembly hole for assembling the green semiconductor light-emitting element, and a third assembly hole for assembling the blue semiconductor light-emitting element. For example, the red semiconductor light-emitting element may have a circular shape, the green semiconductor light-emitting element may have a first oval shape having a first minor axis and a first major axis, and the blue semiconductor light-emitting element may have a second oval shape having a second minor axis and a second major axis, but is not limited thereto. The second major axis of the oval shape of the blue semiconductor light-emitting element may be larger than the first major axis of the oval shape of the green semiconductor light-emitting element, and the second minor axis of the oval shape of the blue semiconductor light-emitting element may be smaller than the first minor axis of the oval shape of the green semiconductor light-emitting element.

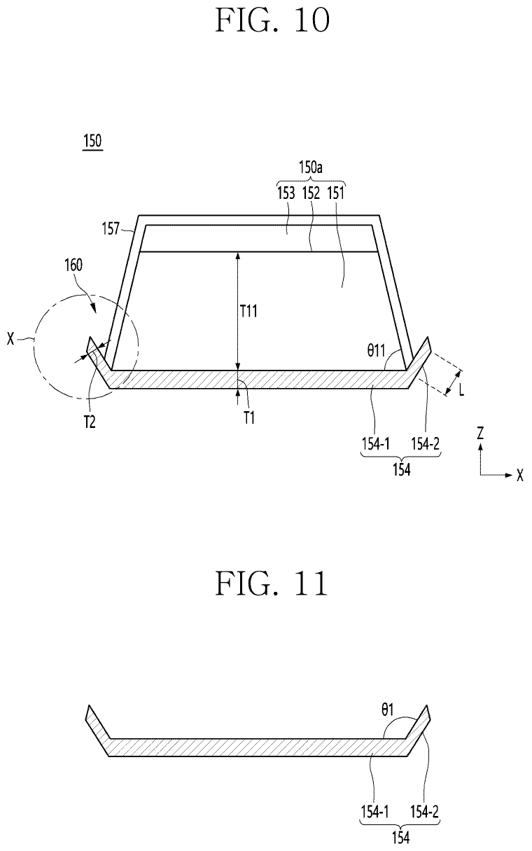

Meanwhile, the method of mounting the semiconductor light-emitting element 150 on the substrate 200 may comprise, for example, a self-assembly method (FIG. 8) and a transfer method.

FIG. 8 is a drawing showing an example in which a light-emitting element according to an embodiment is assembled on a substrate by a self-assembly method.

Based on FIG. 8, an example in which a semiconductor light-emitting element according to an embodiment is assembled on a display panel by a self-assembly method using an electromagnetic field will be described.

The assembly substrate 200 described below may also function as a panel substrate in a display device after assembling the light-emitting element, but the embodiment is not limited thereto.

Referring to FIG. 8, the semiconductor light-emitting element 150 may be put into a chamber 1300 filled with a fluid 1200, and the semiconductor light-emitting element 150 may be moved to the assembly substrate 200 by a magnetic field generated from a assembly device 1100. At this time, the light-emitting element 150 adjacent to an assembly hole 207H of the assembly substrate 200 may be assembled into the assembly hole 207H by the DEP force caused by an electric field of the assembling wirings. The fluid 1200 may be water such as ultrapure water, but is not limited thereto. The chamber may be called a tank, a container, a vessel, etc.

After the semiconductor light-emitting element 150 is put into the chamber 1300, the assembly substrate 200 may be disposed on the chamber 1300. According to an embodiment, the assembly substrate 200 may be put into the chamber 1300.

The semiconductor light-emitting element 150 may be implemented as a vertical-type semiconductor light-emitting element as illustrated, but is not limited thereto, and a lateral-type light-emitting element may be employed.

The semiconductor light-emitting element 150 may comprise a magnetic layer (not illustrated) having a magnetic substance. The magnetic layer may comprise a metal having magnetism, such as nickel (Ni). Since the semiconductor light-emitting element 150 put into the fluid comprises the magnetic layer, it may move to the assembly substrate 200 by a magnetic field generated from the assembly device 1100. The magnetic layer may be disposed on the upper side, the lower side or both sides of the light-emitting element.

The assembly substrate 200 may comprise a pair of a first assembling wiring 201 and a second assembling wiring 202 corresponding to each of the semiconductor light-emitting elements 150 to be assembled. Each of the first assembling wiring 201 and the second assembling wiring 202 may be formed by laminating a single metal or a metal alloy, a metal oxide, etc. in multiple layers. For example, each of the first assembling wiring 201 and the second assembling wiring 202 may be formed by comprising at least one of Cu, Ag, Ni, Cr, Ti, Al, Rh, Pd, Ir, Ru, Mg, Zn, Pt, Au, and Hf, but is not limited thereto.

The first assembling wiring 201 and the second assembling wiring 202 form an electric field when an AC voltage is applied, and the semiconductor light-emitting element 150 inserted into the assembly hole 207H may be fixed by the DEP force caused by the electric field. A gap between the first assembling wiring 201 and the second assembling wiring 202 may be smaller than a width of the semiconductor light-emitting element 150 and a width of the assembly hole 207H, and the assembly position of the semiconductor light-emitting element 150 may be fixed more precisely using the electric field.

An insulating layer 215 is formed on the first assembling wiring 201 and the second assembling wiring 202 to protect the first assembling wiring 201 and the second assembling wiring 202 from the fluid 1200 and prevent leakage of current flowing in the first assembling wiring 201 and the second assembling wiring 202. For example, the insulating layer 215 may be formed as a single layer or multiple layers of an inorganic insulator such as silica or alumina or an organic insulator. The insulating layer 215 may have a minimum thickness to prevent damage to the first assembling wiring 201 and the second assembling wiring 202 during assembly of the semiconductor light-emitting element 150, and may have a maximum thickness to stably assemble the semiconductor light-emitting element 150.

A partition wall 207 may be formed on the upper part of the insulating layer 215. A part of the partition wall 207 may be positioned in an upper part the first assembling wiring 201 and the second assembling wiring 202, and the remaining regions may be positioned in an upper part the assembly substrate 200.

Meanwhile, when manufacturing the assembly substrate 200, a part of the partition wall formed in the upper part of the insulating layer 215 may be removed, so that assembly holes 207H in which each of the semiconductor light-emitting elements 150 is coupled and assembled to the assembly substrate 200 may be formed.

The assembly substrate 200 has assembly holes 207H formed in which the semiconductor light-emitting elements 150 are coupled, and a surface on which the assembly holes 207H are formed may be in contact with the fluid 1200. The assembly holes 207H may guide the exact assembly positions of the semiconductor light-emitting elements 150.

Meanwhile, the assembly holes 207H may have a shape and size corresponding to the shape of the semiconductor light-emitting elements 150 to be assembled at the corresponding positions. Accordingly, it is possible to prevent another semiconductor light-emitting element from being assembled in the assembly hole 207H or a plurality of semiconductor light-emitting elements from being assembled.

Referring again to FIG. 8, after the assembly substrate 200 is disposed in the chamber, the assembly device 1100 applying a magnetic field may move along the assembly substrate 200. The assembly device 1100 may be a permanent magnet or an electromagnet.

The assembly device 1100 may move in contact with the assembly substrate 200 in order to maximize a region affected by the magnetic field within the fluid 1200. Depending on the embodiment, the assembly device 1100 may comprise a plurality of magnetic substances or may comprise a magnetic substance having a size corresponding to the assembly substrate 200. In this instance, the movement distance of the assembly device 1100 may be limited within a predetermined range.

The semiconductor light-emitting element 150 in the chamber 1300 may move toward the assembly device 1100 and the assembly substrate 200 by the magnetic field generated by the assembly device 1100.

The semiconductor light-emitting element 150 may be fixed by entering the assembly hole 207H by the DEP force formed by the electric field between the assembling wirings 201 and 202 while moving toward the assembly device 1100.

Specifically, the first and second assembling wirings 201 and 202 form an electric field by the AC power source, and the DEP force may be formed between the assembling wirings 201 and 202 by this electric field. The semiconductor light-emitting element 150 may be fixed to the assembly hole 207H on the assembly substrate 200 by this DEP force.

At this time, a predetermined solder layer (not illustrated) may be formed between the light-emitting element 150 assembled on the assembly hole 207H of the assembly substrate 200 and the assembling wirings 201 and 202 to improve the binding strength of the light-emitting element 150.

In addition, a molding layer (not illustrated) may be formed on the assembly hole 207H of the assembly substrate 200 after assembly. The molding layer may be a transparent resin or a resin containing a reflective material or a scattering material.

By the self-assembly method using the electromagnetic field described above, the time required for each semiconductor light-emitting element to be assembled on the substrate can be drastically shortened, so that a large-area, high-pixel display can be implemented more quickly and economically.

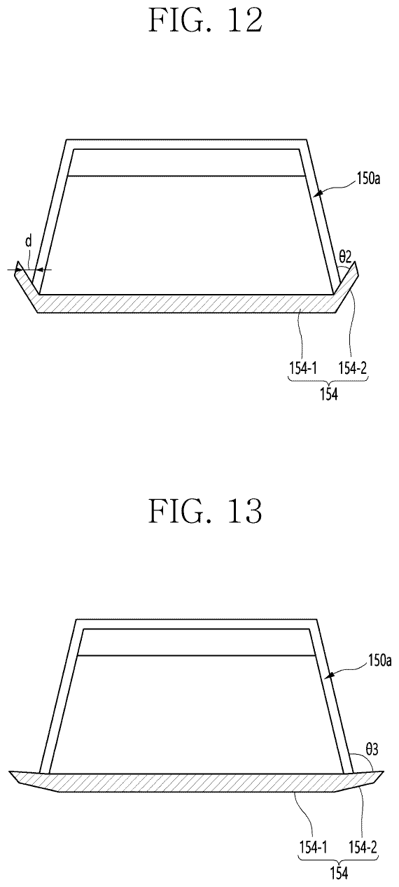

Hereinafter, various embodiments for solving the above-described problems will be described with reference to FIGS. 9 to 26. Any omitted descriptions herein may be easily understood from the descriptions described above in relation to FIGS. 3 to 8 and the corresponding drawings.

### Semiconductor Light-Emitting Element

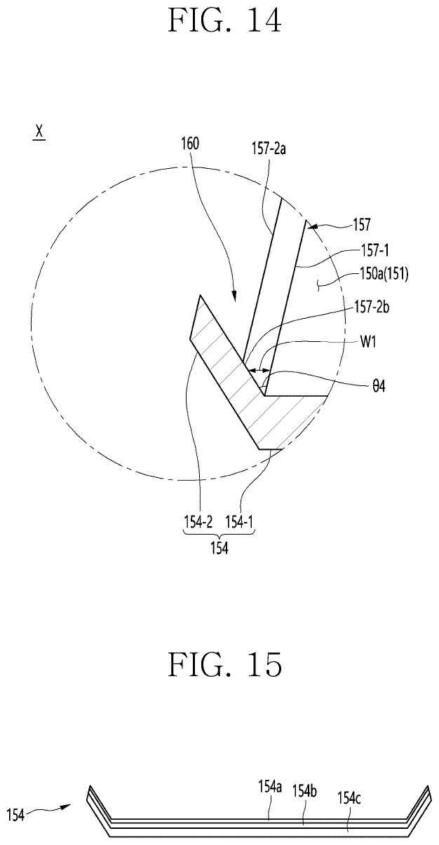

FIG. 9 is a perspective view illustrating a semiconductor light-emitting element according to an embodiment. FIG. 10 is a cross-sectional view illustrating a semiconductor light-emitting element according to an embodiment.

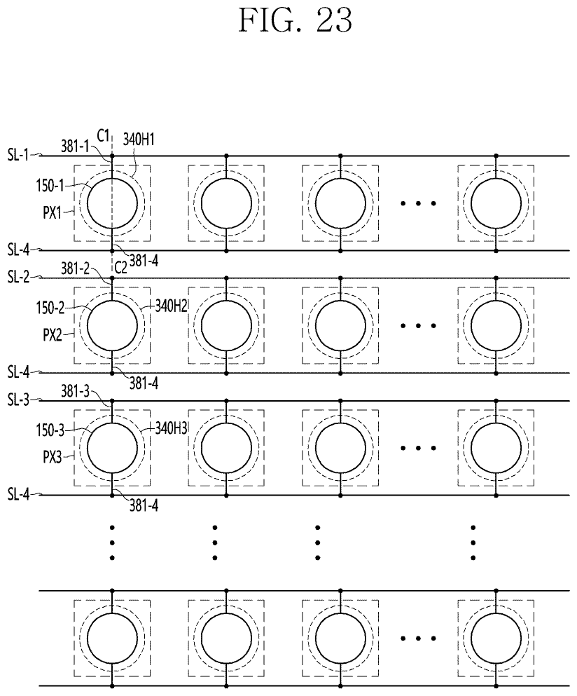

Referring to FIGS. 9 and 10, the semiconductor light-emitting element 150 according to the embodiment may be one of the semiconductor light-emitting elements (FIG. 23) provided in a plurality of pixels, respectively, to display an image. That is, the semiconductor light-emitting element 150 according to the embodiment may be one of a first semiconductor light-emitting element 150-1, a second semiconductor light-emitting element 150-2, and a third semiconductor light-emitting element 150-3 illustrated in FIG. 23.

The semiconductor light-emitting element 150 according to the embodiment may comprise a light-emitting layer 150a, a passivation layer 157, and a first electrode 154.

In the embodiment, the light-emitting layer 150a may have a trapezoidal shape, but is not limited thereto. The light-emitting layer 150a may have a mesa structure. That is, a size of an upper side of the light-emitting layer 150a may be smaller than a size of a lower side. A side portion of the light-emitting layer 150a may have an acute angle θ11 with respect to the lower side of the light-emitting layer 150a. The side portion of the light-emitting layer 150a may have an obtuse angle with respect to the upper side of the light-emitting layer 150a.

The light-emitting layer 150a may comprise at least one or more first conductivity type semiconductor layer 151, an active layer 152, and at least one or more second conductivity type semiconductor layer 153. For example, the first conductivity type semiconductor layer 151 may be an n-type semiconductor layer, and the second conductivity type semiconductor layer 153 may be a p-type semiconductor layer, but is not limited thereto.

For example, the first conductivity type semiconductor layer 151, the active layer 152, and the second conductivity type semiconductor layer 153 may be sequentially deposited on a sapphire substrate using a deposition equipment such as MOCVD. The sapphire substrate may be removed later. For example, the first conductivity type semiconductor layer 151 may be deposited on the sapphire substrate, the active layer 152 may be deposited on the first conductivity type semiconductor layer 151, and the second conductivity type semiconductor layer 153 may be deposited on the active layer 152. The first conductivity type semiconductor layer 151, the active layer 152, and the second conductivity type semiconductor layer 153 may be formed of a compound semiconductor material.

The passivation layer 157 may be formed of an insulating material. The passivation layer 157 may protect the light-emitting layer 150a. The passivation layer 157 may affect the strength of the DEP force for assembling the semiconductor light-emitting element 150 during self-assembly.

The passivation layer 157 may surround the light-emitting layer 150a. The passivation layer 157 may surround the remaining region except for the lower side of the light-emitting layer 150a.

For example, the passivation layer 157 may surround the perimeter of an outer side surface of the first conductivity type semiconductor layer 151. For example, the passivation layer 157 may surround the perimeter of an outer side surface of the active layer 152. For example, the passivation layer 157 may surround the perimeter of an outer side surface of the second conductivity type semiconductor layer 153. For example, the passivation layer may be disposed on an upper surface of the second conductivity type semiconductor layer 153.

The first electrode 154 may electrically connect the light-emitting layer 150a to the outside.

In an embodiment, the first electrode 154 may comprise a lower electrode 154-1 and a side electrode 154-2.

The lower electrode 154-1 may be disposed on a lower side of the light-emitting layer 150a. The lower electrode 154-1 may be disposed on a lower side of the first conductivity type semiconductor layer 151. The lower electrode 154-1 may be in contact with a lower surface of the first conductivity type semiconductor layer 151, but is not limited thereto.

The side electrode 154-2 may extend in a lateral direction from the lower electrode 154-1.

The side electrode 154-2 may extend from an end of the lower electrode 154-1 onto a side portion of the light-emitting layer 150a. The side electrode 154-2 may extend in a diagonal direction from the end of the lower electrode 154-1. In other words, the side electrode 154-2 may not extend in a horizontal direction from the end of the lower electrode 154-1, but may extend in a diagonal direction with respect to the lower electrode 154-1. That is, the side electrode 154-2 may be bent upward from the end of the lower electrode 154-1.

Meanwhile, the side electrode 154-2 may be positioned on the side portion of the light-emitting layer 150a, but does not contact the side portion of the light-emitting layer 150a. That is, the side electrode 154-2 may be spaced apart from the side portion of the light-emitting layer 150a. In this instance, a recess 160 may be formed by a separation space between the side electrode 154-2 and the side portion of the light-emitting layer 150a. The recess 160 may have a “V” shape when viewed from the side.

Meanwhile, the side electrode 154-2 may be disposed along the perimeter of the side portion of the light-emitting layer 150a. That is, the side electrode 154-2 may have a closed loop structure along the perimeter of the side portion of the light-emitting layer 150a.

As an example, the side electrode 154-2 may be formed integrally with the lower electrode 154-1. For example, the lower electrode 154-1 and the side electrode 154-2 may be formed simultaneously by performing the same process with the same metal.

As another example, the side electrode 154-2 may be formed separately from the lower electrode 154-1. In this instance, the lower electrode 154-1 and the side electrode 154-2 may each be formed of different metals. For example, after the lower electrode 154-1 is formed on the lower side of the light-emitting layer 150a using a first metal, the side electrode 154-2 may be formed on the side portion of the light-emitting layer 150a using a second metal. At this time, the lower electrode 154-1 and the side electrode 154-2 may be in contact with each other, but is not limited thereto.

Meanwhile, a length L of the side electrode 154-2 may be smaller than a thickness T11 of the first conductivity type semiconductor layer 151 of the light-emitting layer 150a. When the length L of the side electrode 154-2 is larger than the thickness T11 of the first conductivity type semiconductor layer 151 of the light-emitting layer 150a and the electrical wiring process is performed after the semiconductor light-emitting element 150 is assembled, an electrical short may occur in which the upper wiring (referred to as the second electrode wiring) connected to the second conductivity type semiconductor layer 153 is connected to the side electrode 154-2.

In addition, a thickness T1 of the lower electrode 154-1 may be larger than a thickness T2 of the side electrode 154-2, but is not limited thereto. Since the thickness T1 of the lower electrode 154-1 is formed thick, ohmic property, electric conduction property, magnetization property, reflection property, etc. can be improved.

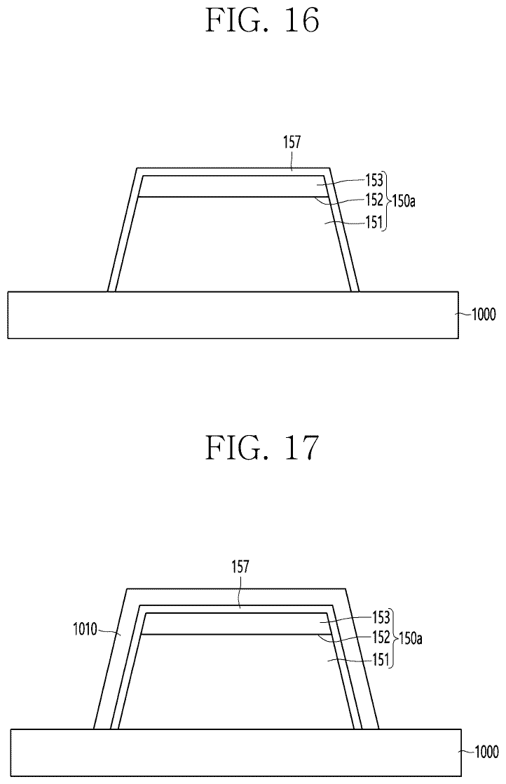

As illustrated in FIG. 11, the side electrode 154-2 may have an obtuse angle θ1 with respect to the horizontal surface of the lower electrode 154-1. For example, the side electrode 154-2 may be inclined at an angle θ1 of 100° or more with respect to the horizontal surface of the lower electrode 154-1. In contrast, the side portion of the light-emitting layer 150a may have an acute angle θ11 with respect to the lower side of the light-emitting layer 150a. Accordingly, since the side electrode 154-2 extends in a diagonal direction from the end of the lower electrode 154-1, the side electrode 154-2 may be spaced apart from the side portion of the light-emitting layer 150a. That is, the side electrode 154-2 may be spatially spaced apart from the passivation layer 157 disposed on the side portion of the light-emitting layer 150a.

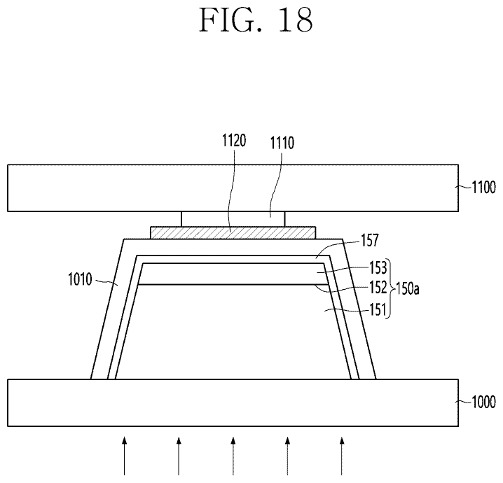

As illustrated in FIG. 12, a distance d between the side electrode 154-2 and the side portion of the light-emitting layer 150a may increase along an upward direction. For example, the distance d between the side electrode 154-2 and the side portion of the light-emitting layer 150 a from an upper surface of the lower electrode 154-1 may be 0. For example, the distance d between the side electrode 154-2 and the side portion of the light-emitting layer 150a may increase as the distance increases in an upward direction from the upper surface of the lower electrode 154-1.

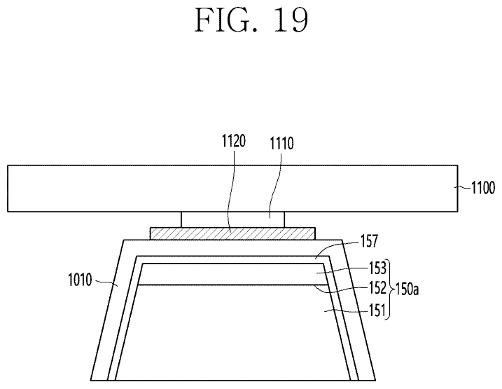

The side electrode 154-2 may have an acute angle θ2 (FIG. 12) or an obtuse angle θ3 (FIG. 13) with respect to the side portion of the light-emitting layer 150a. Accordingly, the side electrode 154-2 may be spatially spaced from the side portion of the light-emitting layer 150a.

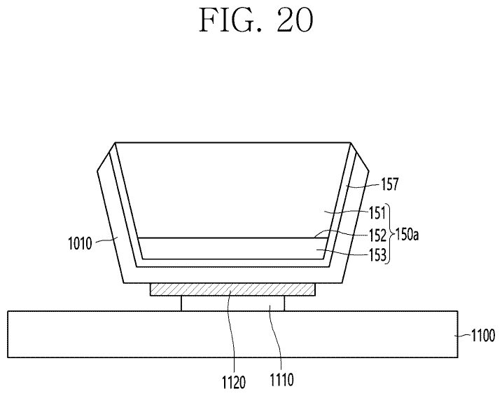

Meanwhile, as illustrated in FIG. 14, the passivation layer 157 may have an inner side surface 157-1, a first outer side surface 157-2a, and a second outer side surface 157-2b.

The inner side surface 157-1 may be in contact with the side portion of the light-emitting layer 150a. That is, the inner side surface 157-1 may be in contact along the perimeter of the side portion of the light-emitting layer 150a. The first outer side surface 157-2a may be the opposite side of the inner side surface 157-1. That is, the first outer side surface 157-2a may be a surface parallel to the inner side surface 157-1, but is not limited thereto.

The second outer side surface 157-2b may be positioned below the first outer side surface 157-2a. The second outer side surface 157-2b may be brought closer to the inner side surface 157-1 along a downward direction. For example, the inner side surface 157-1 and the second outer side surface 157-2b may meet each other on the upper surface of the lower electrode 154-1. That is, the upper surface of the lower electrode 154-1, the inner side surface 157-1, and the second outer side surface 157-2b may contact each other. Accordingly, a width W1 between the inner side surface 157-1 and the second outer side surface 157-2b may be reduced along a downward direction.

The second outer side surface 157-2b may have an acute angle θ4 with respect to the inner side surface 157-1. Although the drawing shows that the second outer side surface 157-2b has an acute angle θ4 with respect to the inner side surface 157-1, it may have an obtuse angle. When the second outer side surface 157-2b has an obtuse angle with respect to the inner side surface 157-1, the side electrode 154-2 may be positioned on a nearly identical horizontal line with the lower electrode 154-1.

Meanwhile, the side electrode 154-2 may be in contact with the second outer side surface 157-2b of the passivation layer 157. In this way, since the side electrode 154-2 is in contact with the second outer side surface 157-2b of the passivation layer 157, an inclination angle θ4 of the second outer side surface 157-2b may be an inclination angle of the side electrode 154-2. That is, as the inclination angle θ4 of the second outer side surface 157-2b with respect to the inner side surface 157-1 decreases, the side electrode 154-2 may be more and more vertically erected. As the inclination angle θ4 of the second outer side surface 157-2b with respect to the inner side surface 157-1 increases, the side electrode 154-2 may lie more and more toward the horizontal. Therefore, by adjusting the inclination angle θ4 of the second outer side surface 157-2b, an inclination of the side electrode 154-2 may be adjusted.

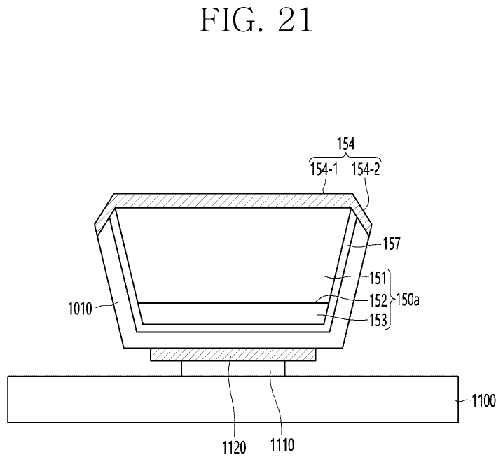

Meanwhile, as illustrated in FIG. 15, the first electrode 154 may comprise a plurality of layers 154a, 154b, and 154c. For example, the first electrode 154 may comprise a first layer 154a, a second layer 154b, and a third layer 154c. Although three layers 154a, 154b, and 154c are illustrated in the drawing, more layers may be included. Although not illustrated, a reflective layer may be further included. The reflective layer may be disposed on the first layer 154a or between the first layer 154a and the second layer 154b.

The first layer 154a may be an ohmic layer, the second layer 154b may be an electrode layer, and the third layer 154c may be a magnetic layer.

For example, Au/Ge/Au may be used as the ohmic layer 154a. For example, Au, Cu, Pt, etc. may be used as the electrode layer 154b. For example, Ni, Co, etc. may be used as the magnetic layer 154c.

The electrical resistance with the first conductivity type semiconductor layer 151 may be lowered by the ohmic layer 154a, so that current supply can be easy and current loss can be reduced, thereby reducing power consumption. The electrode layer 154b may be a material with excellent electrical conductivity, so that current supply can be easy and current loss can be reduced together with the ohmic layer 154a.

The magnetic layer 154c may be made of a material with excellent magnetization, so that it can be easily magnetized by a magnet. As will be explained later, the semiconductor light-emitting element 150 may be assembled on the display substrate using a magnetic field and an electric field by a self-assembly method. That is, the semiconductor light-emitting element 150 may be moved in a fluid using a magnet. At this time, the magnetic layer 154c may be provided on the semiconductor light-emitting element 150 to increase the response speed of the semiconductor light-emitting element 150. In particular, since Ni, etc., which has excellent magnetization, is used as the magnetic layer 154c, the semiconductor light-emitting element 150 can respond to the movement of the magnet more quickly, thereby improving the assembly speed of the semiconductor light-emitting element 150.

Meanwhile, since the second outer side surface 157-2b is inclined with respect to the inner side surface 157-1, it may be referred to as an inclined surface. The inclination of the side electrode 154-2 may vary depending on the degree of inclination of the second outer side surface 157-2b.

In addition, since the side electrode 154-2 protrudes in a diagonal direction from the end of the lower electrode 154-1, it may be referred to as a protruding electrode.

The semiconductor light-emitting element 150 described above may be a vertical-type semiconductor light-emitting element, but may also be equally adopted for a lateral-type semiconductor light-emitting element or a flip-chip type semiconductor light-emitting element.

According to the embodiment, the side electrode 154-2 may be disposed on the side portion of the light-emitting layer 150a, and may does not come into contact with the side portion of the light-emitting layer 150a. Accordingly, the side electrode 154-2 is not formed up to the position of the uppermost layer of the passivation layer 157, that is, the upper surface of the second conductivity type semiconductor layer 153. Therefore, when the semiconductor light-emitting element 150 is self-assembled on the display substrate and an electrical wiring is formed, an electrical short between the wiring and the side electrode 154-2 can be prevented. In this way, since an electrical short between the side electrode 154-2 and the wiring is prevented, a lighting failure can be prevented, so that the product quality can be improved.

According to an embodiment, when the semiconductor light-emitting element 150 is self-assembled on a display substrate and then the wiring is connected to the side electrode 154-2, as the wiring is formed on the outer side surface of the side electrode 154-2 as well as in the recess 160 between the side electrode 154-2 and the side portion of the light-emitting layer 150a, the contact area between the wiring and the side electrode 154-2 can be maximized, so that the fixing force between the side electrode 154-2 and the wiring can be improved.

According to an embodiment, the first electrode 154 of the semiconductor light-emitting element 150 may comprise a magnetic layer 154c, so that the response speed to the movement of the magnet during self-assembly can be increased, thereby improving the assembly speed of the semiconductor light-emitting element 150.

### Manufacturing Process of Semiconductor Light-Emitting Element

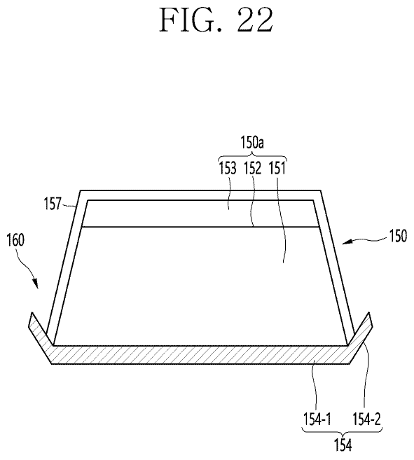

FIGS. 16 to 22 illustrate a manufacturing process of a semiconductor light-emitting element according to an embodiment.

As illustrated in FIG. 16, a light-emitting layer 150a may be formed on a wafer 1000, and a passivation layer 157 may be formed around the light-emitting layer 150a.

Specifically, at least one or more first conductivity type semiconductor layer 151, an active layer 152, and at least one or more second conductivity type semiconductor layer 153 may be deposited on the wafer 1000 using a MOCVD equipment.

Thereafter, the second conductivity type semiconductor layer 153, the active layer 152, and the first conductivity type semiconductor layer 151 may be removed using an etching process, so that an upper surface of the wafer 1000 may be exposed, thereby forming the light-emitting layer 150a. Although one light-emitting layer 150a is illustrated in the drawing, numerous light-emitting layers 150a may be formed on the wafer 1000. The upper surface of the wafer 1000 between the adjacent light-emitting layers 150a may be exposed by the second conductivity type semiconductor layer 153, the active layer 152, and the first conductivity type semiconductor layer 151.

By performing mesa etching, a side portion of the light-emitting layer 150a composed of the first conductivity type semiconductor layer 151, the active layer 152, and the second conductivity type semiconductor layer 153 may have an inclined surface. That is, the side portion of the light-emitting layer 150a may have an acute angle with respect to a lower side of the light-emitting layer 150a.

Thereafter, a passivation layer 157 may be formed on the wafer 1000. For example, the passivation layer 157 may surround the light-emitting layer 150a.

As illustrated in FIG. 17, a deposition prevention layer 1010 may be formed on the passivation layer 157. The deposition prevention layer 1010 may surround the passivation layer 157.

The passivation layer 157 and the deposition prevention layer 1010 may surround the light-emitting layer 150a and contact the upper surface of the wafer 1000.

For example, the deposition prevention layer 1010 may be formed of, for example, an organic material. For example, the deposition prevention layer 1010 may be benzocyclobutene (BCB), but is not limited thereto.

For example, the deposition prevention layer 1010 may be formed by itself as a by-products. That is, by-products generated in various processes such as bonding to a temporary substrate (FIG. 18), separation of the wafer 1000 (FIG. 19), and etching of the passivation layer 157 (FIG. 20) may be deposited on the passivation layer 157 and used as the deposition prevention layer 1010.

As illustrated in FIG. 18, a temporary substrate 1100 may be attached to an upper side of the light-emitting layer 150a. The temporary substrate 1100 may be attached to the upper side of the light-emitting layer 150a using an adhesive 1110.

Meanwhile, a sacrificial layer 1120 may be formed on the upper side of the light-emitting layer 150a. The sacrificial layer 1120 may be used later to separate the light-emitting layer 150a from the temporary substrate 1100. That is, by removing the sacrificial layer 1120, the light-emitting layer 150a may be separated from the temporary substrate 1100.

The sacrificial layer 1120 may be formed of a metal such as Al or a photosensitive material.

Meanwhile, after the temporary substrate 1100 is attached to the upper side of the light-emitting layer 150a, the LLO process may be performed so that the wafer 1000 may be separated from the light-emitting layer 150a. That is, the laser may be irradiated to a boundary between the wafer 1000 and the light-emitting layer 150a, and the laser may be absorbed at the boundary. Accordingly, the compound material at the boundary, that is, GaN, may be decomposed into Ga and N₂, so that the wafer 1000 may be separated from the light-emitting layer (FIG. 19).

As illustrated in FIG. 19, by separating the wafer 1000, the light-emitting layer 150a, the passivation layer 157, and the deposition prevention layer 1010, which were in contact with the wafer 1000, may be positioned on the same horizontal line.

As illustrated in FIG. 20, the passivation layer 157 and the deposition prevention layer 1010, which are positioned on the same horizontal line as the light-emitting layer 150a, may be etched to have an inclined surface with respect to the surface of the light-emitting layer 150a. At this time, an inclination of the inclined surface of the passivation layer 157 and the deposition prevention layer 1010 may be determined by an inclination of the side electrode 154-2 of the first electrode 154, which will be described later. That is, the inclination of the side electrode 154-2 of the first electrode may correspond to the inclination of the inclined surface of the passivation layer 157 and the deposition prevention layer 1010.

Although the inclined surface is depicted as a straight surface in the drawing, it may have a round surface.

As illustrated in FIG. 21, a first electrode 154 may be formed by depositing a metal film on the light-emitting layer 150a, the passivation layer 157, and the deposition prevention layer 1010 using a deposition process.

For example, a sputtering process may be performed using an E-beam deposition equipment, so that the metal film may be deposited on the light-emitting layer 150a, the passivation layer 157, and the deposition prevention layer 1010. The E-beam deposition equipment may control the directionality of the metal particles. That is, the E-beam deposition equipment may control the metal particles to proceed in a vertical direction. Therefore, the metal particles may be deposited on the light-emitting layer 150a, the passivation layer 157, and the deposition prevention layer 1010 in a vertical direction by the E-beam deposition equipment. In this way, since the metal particles may be deposited in a vertical direction, the metal particles may not be deposited on the side surface of the deposition prevention layer 1010. In particular, since the deposition prevention layer 1010 is made of a material having low reactivity with metal particles, the metal particles may be released without being deposited on the deposition prevention layer 1010. Therefore, a metal film, which is a laminate of metal particles, may be only deposited on the upper surface of each of the light-emitting layer 150a, the passivation layer 157, and the deposition prevention layer 1010, and may be not formed on the side surface of the deposition prevention layer 1010.

Meanwhile, the upper surface of the light-emitting layer 150a has a horizontal surface that is perpendicular to the direction in which the metal particles advance, whereas the upper surface of each of the passivation layer 157 and the deposition prevention layer 1010 have an inclined surface that are inclined with respect to the direction in which the metal particles advance. Accordingly, since the metal particles are more easily deposited on the upper surface of the light-emitting layer 150a than on the upper surface of each of the passivation layer 157 and the deposition prevention layer 1010, the thickness of the metal film on the upper surface of the light-emitting layer 150a may be thicker than the thickness of the metal film on the upper surface of each of the passivation layer 157 and the deposition prevention layer 1010. The metal film on the upper surface of the light-emitting layer 150a may be a lower electrode 154-1, and the metal film on the upper surface of each of the passivation layer 157 and the deposition prevention layer 1010 may be a side electrode 154-2. A first electrode 154 may be formed by the lower electrode 154-1 and the side electrode 154-2.

As described above, the first electrode 154 may comprise a plurality of layers (154a, 154b, 154c of FIG. 15). To this end, the first layer 154a, the second layer 154b, and the third layer 154c may be sequentially deposited on the light-emitting layer 150a, the passivation layer 157, and the deposition prevention layer 1010.

As illustrated in FIG. 22, the semiconductor light-emitting element 150 may be manufactured by performing an etching process to remove the deposition prevention layer 1010. The deposition prevention layer 1010 may be removed using an exposure or dry etching process, but is not limited thereto.

Thereafter, the semiconductor light-emitting element 150 may be separated from the temporary substrate 1100 by performing a wet etching process to remove the sacrificial layer 1120.

### Display Device

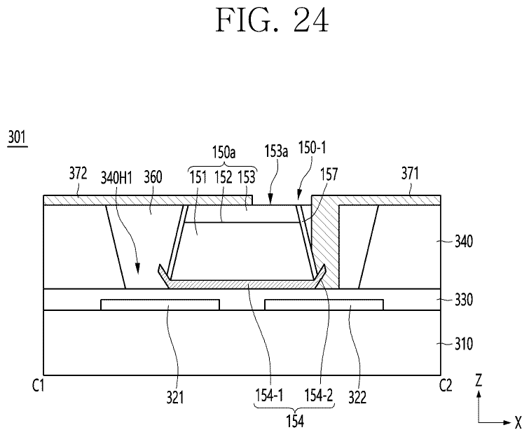

FIG. 23 is a circuit diagram illustrating a display device according to an embodiment. FIG. 24 is a cross-sectional view illustrating a display device according to the first embodiment.

Referring to FIG. 23 and FIG. 24, the display device 301 according to the first embodiment may comprise a substrate 310, a plurality of semiconductor light-emitting elements 150-1 to 150-3, and a plurality of signal lines SL-1 to SL-4.

The plurality of semiconductor light-emitting elements 150-1 to 150-3 may each have the same shape or structure as the semiconductor light-emitting element 150 illustrated in FIG. 9 and FIG. 10.

The substrate 310 may serve as a supporting member that supports various components of the display device 301.

A plurality of subpixels PX1, PX2, and PX3 may be defined on the substrate 310. For example, a unit pixel may be configured by a first subpixel PX1, a second subpixel PX2, and a third subpixel PX3.

A plurality of assembly holes 340H1 to 340H3 may be provided on the substrate 310. For example, a partition wall 340 may be disposed on the substrate 310, and a plurality of assembly holes 340H1 to 340H3 may be formed in the partition wall 340.

At least one assembly hole 340H1 to 340H3 may be provided in one subpixel PX1, PX2, and PX3. For example, a first assembly hole 340H1 may be disposed in a first subpixel PX1, a second assembly hole 340H2 may be disposed in a second subpixel PX2, and a third assembly hole 340H3 may be disposed in a third subpixel PX3.

A plurality of semiconductor light-emitting elements 150-1 to 150-3 may be disposed in the plurality of subpixels PX1, PX2, and PX3, respectively. The plurality of semiconductor light-emitting elements may comprise a first semiconductor light-emitting element 150-1, a second semiconductor light-emitting element 150-2, and a third semiconductor light-emitting element 150-3. The first semiconductor light-emitting element 150-1, the second semiconductor light-emitting element 150-2, and the third semiconductor light-emitting element 150-3 may emit light of different colors. For example, the first semiconductor light-emitting element 150-1 may emit red light, the second semiconductor light-emitting element 150-2 may emit green light, and the third semiconductor light-emitting element 150-3 may emit blue light, but is not limited thereto.

For example, the first semiconductor light-emitting element 150-1 may be disposed in the first subpixel PX1, the second semiconductor light-emitting element 150-2 may be disposed in the second subpixel PX2, and the third semiconductor light-emitting element 150-3 may be disposed in the third subpixel PX3. For example, the first semiconductor light-emitting element 150-1 may be disposed in the first assembly hole 340H1, the second semiconductor light-emitting element 150-2 may be disposed in the second assembly hole 340H2, and the third semiconductor light-emitting element 150-3 may be disposed in the third assembly hole 340H3.

In the embodiment, the plurality of semiconductor light-emitting elements 150-1 to 150-3 may be assembled into the plurality of assembly holes 340H1 to 340H3, respectively, using a self-assembly method. Since the self-assembly method has been described in detail above with reference to FIG. 6, a detailed description thereof will be omitted. The plurality of semiconductor light-emitting elements 150-1 to 150-3 may be assembled into the plurality of assembly holes 340H1 to 340H3 separately, respectively. The plurality of semiconductor light-emitting elements 150-1 to 150-3 may be assembled into the plurality of assembly holes 340H1 to 340H3 simultaneously.

In order to utilize the self-assembly method, the first assembling wiring 321 and the second assembling wiring 322 may be disposed, and an insulating layer (330, hereinafter referred to as a first insulating layer) may be disposed on the first assembling wiring 321 and the second assembling wiring 322 to insulate the first assembling wiring 321 and the second assembling wiring 322. In this instance, a bottom portion of the assembly holes 340H1 to 340H3 may be a part of the upper surface of the first insulating layer 330. That is, a part of the upper surface of the first insulating layer 330 may be exposed by the assembly holes 340H1 to 340H3.

For example, shapes of the assembly holes 340H1 to 340H3 may correspond to shapes of the semiconductor light-emitting elements 150-1 to 150-3, respectively. In the embodiment, since the semiconductor light-emitting elements 150-1 to 150-3 have circular shapes when viewed from above, the assembly holes 340H1 to 340H3 may also have circular shapes. For example, a size of each of the assembly holes 340H1 to 340H3 may be larger than a size of each of the semiconductor light-emitting elements 150-1 to 150-3. That is, when the semiconductor light-emitting elements 150-1 to 150-3 are inserted into the assembly holes 340H1 to 340H3, the outer side surfaces of the semiconductor light-emitting elements 150-1 to 150-3 may be spaced apart from the inner side surfaces of the assembly holes 340H1 to 340H3, respectively.

After the semiconductor light-emitting elements 150-1 to 150-3 are assembled in the assembly holes 340H1 to 340H3, an insulating layer (360, hereinafter referred to as a second insulating layer) may be formed in the assembly holes 340H1 to 340H3. Although not illustrated, a black matrix may be disposed between the subpixels PX1, PX2, and PX3 to distinguish between the subpixels PX1, PX2, and PX3. The black matrix may be disposed on the partition wall 340 excluding the assembly holes 340H1 to 340H3 between the partition wall 340 and the second insulating layer 360, but is not limited thereto.

The upper surface of the second insulating layer 360 and the upper surface of the partition wall 340 may be positioned on the same horizontal line, but is not limited thereto. The upper surface of the second insulating layer 360 and the upper surface of the partition wall 340 are planarization surfaces, which facilitate the formation of the first electrode wiring 371 and the second electrode wiring 372 to be formed later and prevent short circuits.

Meanwhile, a plurality of signal lines SL-1 to SL-4 may be disposed around the plurality of assembly holes 340H1 to 340H3, respectively. Although not illustrated, a driving transistor (DT of FIG. 3) may be connected between each of the plurality of signal lines SL-1 to SL-4 and the subpixels PX1, PX2, and PX3.

The plurality of signal lines SL-1 to SL-4 may be connected to each of the plurality of subpixels PX1, PX2, and PX3.

For example, the plurality of signal lines may comprise a first signal line SL-1, a second signal line SL-2, a third signal line SL-3, and a fourth signal line SL-4. The first signal line SL-1, the second signal line SL-2, the third signal line SL-3, and the fourth signal line SL-4 may be disposed lengthwise along the first direction X. The first signal line SL-1, the second signal line SL-2, the third signal line SL-3, and the fourth signal line SL-4 may be disposed parallel to each other, but is not limited thereto.

As illustrated in FIG. 23, a first semiconductor light-emitting element 150-1 may be disposed in each of a plurality of first subpixels arranged along the first direction X. A second semiconductor light-emitting element 150-2 may be disposed in each of a plurality of second subpixels arranged along the first direction X. A third semiconductor light-emitting element 150-3 may be disposed in each of a plurality of third subpixels arranged along the first direction X.

The first signal line SL-1 may be disposed on one side of each of the first semiconductor light-emitting elements 150-1 arranged along the first direction X and may be connected to each of the first semiconductor light-emitting elements 150-1. The second signal line SL-2 may be disposed on one side of each of the second semiconductor light-emitting elements 150-2 arranged along the first direction X and may be connected to each of the second semiconductor light-emitting elements 150-2. The third signal line SL-3 may be disposed on one side of each of the third semiconductor light-emitting elements 150-3 arranged along the first direction X and may be connected to each of the third semiconductor light-emitting elements 150-3. The fourth signal line SL-4 may be disposed on the other side of each of the first semiconductor light-emitting element 150-1, the second semiconductor light-emitting element 150-2, and the third semiconductor light-emitting element 150-3, and may be connected to each of the first semiconductor light-emitting element 150-1, the second semiconductor light-emitting element 150-2, and the third semiconductor light-emitting element 150-3. The fourth signal line SL-4 may be disposed parallel to the first signal line SL-1, the second signal line SL-2, or the third signal line SL-3, but is not limited thereto.

Although the first semiconductor light-emitting element 150-1, the second semiconductor light-emitting element 150-2, and the third semiconductor light-emitting element 150-3 are illustrated as being arranged along the second direction Y in the drawing, they may also be arranged along the first direction X.

The plurality of signal lines SL-1 to SL-4 may be connected to the plurality of semiconductor light-emitting elements 150-1 to 150-3 via a plurality of connection lines 381-1 to 381-4, respectively. A first signal line SL-1 may be connected to a first semiconductor light-emitting element 150-1 via a first connection line 381-1, a second signal line SL-2 may be connected to a second semiconductor light-emitting element 150-2 via a second connection line 381-2, and a third signal line SL-3 may be connected to a third semiconductor light-emitting element 150-3 via a third connection line 381-3. A fourth signal line SL-4 may be commonly connected to a plurality of semiconductor light-emitting elements 150-1 to 150-3 via a fourth connection line 381-4.

Meanwhile, the display device 301 according to the first embodiment may comprise a first electrode wiring 371 and a second electrode wiring 372.

The first electrode wiring 371 and the second electrode wiring 372 may be disposed horizontally parallel to each other.

For example, the first electrode wiring 371 may be disposed on the semiconductor light-emitting elements 150-1 to 150-3, the second insulating layer 360, and the partition wall 340. The first electrode wiring 371 may extend along the second direction Y on the semiconductor light-emitting elements 150-1 to 150-3.

One side of the first electrode wiring 371 may be connected to the side electrode 154-2 of the first electrode 154 of the semiconductor light-emitting elements 150-1 to 150-3 through the second insulating layer 360. The first electrode wiring 371 may be disposed on the second insulating layer 360 by penetrating the side electrode 154-2 of the first electrode 154 of the semiconductor light-emitting elements 150-1 to 150-3 through the second insulating layer 360, and may extend along the second direction Y on the second insulating layer 360.

The second electrode wiring 372 may be disposed on the second insulating layer 360 and the partition wall 340. The second electrode wiring 372 may be in contact with the upper surface 153a of the first semiconductor light-emitting element 150-1, as illustrated in FIG. 24. The second electrode wiring 372 may be in contact with the upper surface 153a of the second conductivity type semiconductor layer 153 of the first semiconductor light-emitting element 150-1, but is not limited thereto. When a second electrode (not illustrated) is disposed on the second conductivity type semiconductor layer 153, the second electrode wiring 372 may be in contact with the upper surface of the second electrode.

The first electrode wiring 371 and the second electrode wiring 372 may be disposed on the same layer. The first electrode wiring 371 and the second electrode wiring 372 may be disposed to be horizontally spaced apart from each other. The extension direction of the first electrode wiring 371 and the extension direction of the second electrode wiring 372 may be opposite to each other.

The first electrode wiring 371 on the first subpixel where the first semiconductor light-emitting element 150-1 is disposed may be connected to the first signal line SL-1 via the first connection line 381-1. The first electrode wiring 371 on the second subpixel where the second semiconductor light-emitting element 150-2 is disposed may be connected to the second signal line SL-2 via the second connection line 381-2. The first electrode wiring 371 on the third subpixel where the third semiconductor light-emitting element 150-3 is disposed may be connected to the third signal line SL-3 via the third connection line 381-3. Meanwhile, the second electrode wiring 372 on the first subpixel, the second subpixel, and the third subpixel may be connected to the fourth signal line SL-4 via the fourth connection line 381-4.

Meanwhile, as illustrated in FIG. 24, the first electrode wiring 371 may surround the side electrode 154-2 of the first semiconductor light-emitting element 150-1. That is, the first electrode wiring 371 may be disposed between the side portion of the light-emitting layer 150a of the first semiconductor light-emitting element 150-1 and the side electrode 154-2. In addition, the first electrode wiring 371 may be disposed on the outer side surface of the side electrode 154-2. Although not illustrated, in the second subpixel, the first electrode wiring 371 may surround the side electrode 154-2 of the second semiconductor light-emitting element 150-2, and in the third subpixel, the first electrode wiring 371 may surround the side electrode 154-2 of the third semiconductor light-emitting element 150-3.

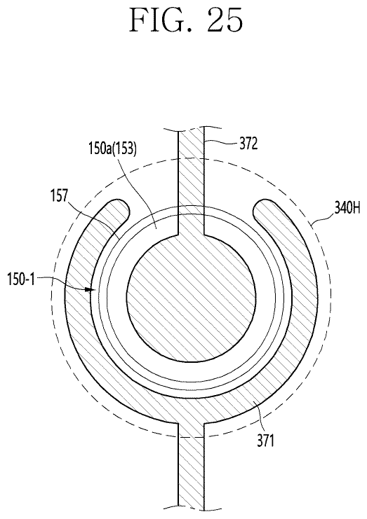

The first electrode wiring 371 may be connected to the side electrode 154-2 along the perimeter of the first semiconductor light-emitting element 150-1. To this end, as illustrated in FIG. 25, a contact hole (not illustrated) may be formed along the perimeter of the first semiconductor light-emitting element 150-1, so that the side electrode 154-2 of the first semiconductor light-emitting element 150-1 may be exposed to the second insulating layer 360, and the first electrode wiring 371 may be formed in the contact hole. Accordingly, the first electrode wiring 371 may be disposed along the perimeter of the first semiconductor light-emitting element 150-1, and may be connected to the side electrode 154-2 of the first semiconductor light-emitting element 150-1 through the contact hole.

As illustrated in FIG. 25, since the first electrode wiring 371 and the second electrode wiring 372 are disposed on the same layer, the contact hole formed along the perimeter of the first semiconductor light-emitting element 150-1 may not be formed in the second insulating layer 360 corresponding to the second electrode wiring 372. Accordingly, the first electrode wiring 371 disposed in the contact hole may be horizontally spaced from the second electrode wiring 372, so that an electrical short circuit can be prevented.

Although not illustrated, the first electrode wiring 371 may be connected to the side electrode 154-2 along the perimeter of the second semiconductor light-emitting element 150-2. The first electrode wiring 371 may be connected to the side electrode 154-2 along the perimeter of the third semiconductor light-emitting element 150-3.

According to the first embodiment, since the first electrode wiring 371 surrounds the side electrode 154-2, the contact area between the first electrode wiring 371 and the side electrode 154-2 may be expanded, so that the fixing force of the first to third semiconductor light-emitting elements 150-1 to 150-3 can be strengthened.

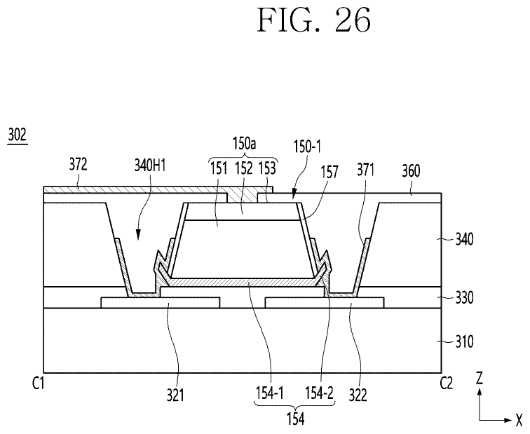

Although FIG. 26 illustrates a cross-sectional view of the first subpixel, the second subpixel and the third subpixel are also the same as the cross-sectional view of the first subpixel, and therefore, the cross-sectional view and the description related thereto of the second subpixel and the third subpixel are omitted.

FIG. 26 is a cross-sectional view illustrating a display device according to the second embodiment.

The second embodiment is the same as the first embodiment (FIG. 24) except for the first electrode wiring 371. In the second embodiment, the same drawing reference numerals are given to components having the same shape, structure and/or function as those in the first embodiment, and detailed descriptions are omitted.

Since the plan view of the display device 302 according to the second embodiment is the same as FIG. 23, reference may be made to FIG. 23.

Referring to FIG. 26, the display device 302 according to the second embodiment may comprise a substrate 310, a first assembling wiring 321, a second assembling wiring 322, a partition wall 340, a plurality of semiconductor light-emitting elements 150-1 to 150-3, a first electrode wiring 371, and a second electrode wiring 372. The display device 302 according to the second embodiment may comprise a plurality of signal lines SL-1 to SL-4.

Since the remaining components except for the first electrode wiring 371 are the same as those of the first embodiment, the description will focus on the first electrode wiring 371.

In the first embodiment, the first electrode wiring 371 and the second electrode wiring 372 may be formed on the same layer at the same time.

In contrast, in the second embodiment, the first electrode wiring 371 may be disposed in a different layer from the second electrode wiring 372.

The first electrode wiring 371 may be formed before the second insulating layer 360 is formed. That is, after the first semiconductor light-emitting element 150-1 is assembled in the first assembly hole 340H1 of the partition wall 340, the first insulating layer 330 may be removed along the perimeter of the first semiconductor light-emitting element 150-1, so that the first assembling wiring 321 and/or the second assembling wiring 322 may be exposed by the first assembly hole 340H1. Thereafter, the first electrode wiring 371 may be formed along the perimeter of the first semiconductor light-emitting element 150-1. Accordingly, the first semiconductor light-emitting element 150-1 and the first assembling wiring 321 and/or the second assembling wiring 322 may be connected by the first electrode wiring 371. That is, one side of the first electrode wiring 371 may surround the side electrode 154-2 of the first semiconductor light-emitting element 150-1, and the other side of the first electrode wiring 371 may contact the upper surface of the exposed first assembling wiring and/or second assembling wiring 322. One side of the first electrode wiring 371 may have a closed loop structure connected to the side electrode 154-2 of the first semiconductor light-emitting element 150-1 along the perimeter of the first semiconductor light-emitting element 150-1, but is not limited thereto.

Thereafter, the second insulating layer 360 may be formed. The second insulating layer 360 may be disposed on the first semiconductor light-emitting element 150-1 and the partition wall 340, and may be disposed in the first assembly hole 340H1. Thereafter, the second electrode wiring 372 may be formed on the second insulating layer 360, and may be connected to the upper side of the first semiconductor light-emitting element 150-1 through the second insulating layer 360.

The second electrode wiring 372 may be vertically overlapped with the first electrode wiring 371 with the second insulating layer 360 interposed therebetween.

Although not illustrated, the structures of the second subpixel and the third subpixel are also the same as the structure of the first subpixel, and therefore, a detailed description thereof will be omitted.

Meanwhile, the display device described above may be a display panel. That is, in the embodiment, the display device and the display panel may be understood to have the same meaning. In an embodiment, the display device in a practical sense may comprise a display panel and a controller (or processor) capable of controlling the display panel to display an image.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### Industrial Applicability

The embodiment may be adopted in the display field for displaying images or information. The embodiment may be adopted in the display field for displaying images or information using a semiconductor light-emitting element. The semiconductor light-emitting element may be a micro-level semiconductor light-emitting element or a nano-level semiconductor light-emitting element.

For example, the embodiment may be adopted in a TV, signage, a smart phone, a mobile phone, a mobile terminal, a HUD for an automobile, a backlight unit for a laptop computer, and a display device for VR or AR.

1. A semiconductor light-emitting element, comprising:
a light-emitting layer;
a passivation layer configured to surround the light-emitting layer;
a lower electrode on a lower side of the light-emitting layer; and
a side electrode configured to extend from an end of the lower electrode onto a side portion of the light-emitting layer,
wherein the side electrode is spaced apart from the side portion of the light-emitting layer.

2. The semiconductor light-emitting element of claim 1, wherein the side electrode is disposed along a perimeter of the side portion of the light-emitting layer.

3. The semiconductor light-emitting element of claim 1, comprising:
a recess between the side electrode and the side portion of the light-emitting layer.

4. The semiconductor light-emitting element of claim 1, wherein the side electrode is disposed in a diagonal direction with respect to the lower electrode.

5. The semiconductor light-emitting element of claim 1, wherein the light-emitting layer comprises:
a first conductivity type semiconductor layer;
an active layer on the first conductivity type semiconductor layer; and
a second conductivity type semiconductor layer on the active layer.

6. The semiconductor light-emitting element of claim 5, wherein a length of the side electrode is smaller than a thickness of the first conductivity type semiconductor layer of the light-emitting layer.

7. The semiconductor light-emitting element of claim 1, wherein the side portion of the light-emitting layer has an acute angle with respect to the lower side of the light-emitting layer.

8. The semiconductor light-emitting element of claim 1, wherein the side electrode has an obtuse angle with respect to a horizontal surface of the lower electrode.

9. The semiconductor light-emitting element of claim 1, wherein a separation distance between the side electrode and the side portion of the light-emitting layer increases along an upward direction.

10. The semiconductor light-emitting element of claim 1, wherein the side electrode has an acute angle with respect to the side portion of the light-emitting layer.

11. The semiconductor light-emitting element of claim 1, wherein the side electrode has an obtuse angle with respect to the side portion of the light-emitting layer.

12. The semiconductor light-emitting element of claim 1, wherein the passivation layer has an inner side surface in contact with the side portion of the light-emitting layer and an outer side surface in contact with the side electrode, and
wherein a width between the inner side surface and the outer side surface decreases along a downward direction.

13. The semiconductor light-emitting element of claim 12, wherein the outer side surface has an acute or obtuse angle with respect to the inner side surface.

14. The semiconductor light-emitting element of claim 1, wherein the lower electrode and the side electrode comprise a magnetic layer.

15. A display device, comprising:
a substrate;
a first assembling wiring on the substrate;
a second assembling wiring on the substrate;
a partition wall having an assembly hole on the first assembling wiring and the second assembling wiring;
a semiconductor light-emitting element in the assembly hole;
a first electrode wiring on a side portion of the semiconductor light-emitting element; and
a second electrode wiring on an upper side of the semiconductor light-emitting element,
wherein the semiconductor light-emitting element comprises:
a light-emitting layer;
a passivation layer configured to surround the light-emitting layer;
a lower electrode on a lower side of the light-emitting layer; and
a side electrode configured to extend from an end of the lower electrode onto a side portion of the light-emitting layer,
wherein the side electrode is spaced apart from the side portion of the light-emitting layer, and
wherein the first electrode wiring is disposed between the side portion of the light-emitting layer and the side electrode.

16. The display device of claim 15, wherein the first electrode wiring is disposed on an outer side surface of the side electrode.

17. The display device of claim 15, wherein the first electrode wiring is connected to the side electrode along a perimeter of the semiconductor light-emitting element.

18. The display device of claim 15, comprising:
an insulating layer in the assembly hole,
wherein the first electrode wiring and the second electrode wiring are disposed on a same horizontal line, and
wherein the first electrode wiring is connected to the side electrode of the semiconductor light-emitting element by penetrating the insulating layer.

19. The display device of claim 15, wherein the first electrode wiring is connected to at least one of the first assembling wiring or the second assembling wiring.
